(19) United States
(12) Patent Application Publication
(10) Pub. No.: US 2019/0378697 A1
(43) Pub. Date: Dec. 12, 2019

(54) APPARATUS AND METHOD FOR PROCESSING SUBSTRATE

(71) Applicant: SEMES CO., LTD., Chungcheongnam-do (KR)

(72) Inventors: JUNG HWAN LEE, Ansan-si (KR); KYUNGHWA JUNG, Cheonan-si (KR)

(21) Appl. No.: 16/423,745

(22) Filed: May 28, 2019

(30) Foreign Application Priority Data
Jun. 7, 2018 (KR) 10-2018-0065593

(51) Int. Cl. H01J 37/32; H01L 21/683

(52) U.S. Cl. CPC H01J 37/32724; H01L 21/6831; H01J 2237/334; H01J 2237/2007; H01J 37/32449

(57) ABSTRACT

An apparatus for processing a substrate includes a process chamber, a support unit that supports the substrate in the process chamber, a gas supply unit that supplies a process gas, and a plasma source that generates plasma from the process gas. The support unit includes an electrostatic chuck, and the apparatus further includes a power supply that supplies a chucking voltage to the electrostatic chuck and a management unit that feedback controls a voltage applied to the power supply for each process and controls a heat transfer gas flow supplied between the substrate and the electrostatic chuck. The management unit includes a first monitoring unit that monitors a physical property change of the substrate. The management unit includes a first controller that performs control to compensate for the chucking voltage by feeding back a chucking force value corresponding to a preset reference value based on the monitored property changes.

### CROSS-REFERENCE TO RELATED APPLICATIONS

A claim for priority under 35 U.S.C. § 119 is made to Korean Patent Application No. 10-2018-0065593 filed on Jun. 7, 2018, in the Korean Intellectual Property Office, the entire contents of which are hereby incorporated by reference.

### BACKGROUND

Embodiments of the inventive concept described herein relate to an apparatus and method for processing a substrate.

A capacitively coupled plasma (CCP) processing method and an inductively coupled plasma (ICP) processing method are used to process surfaces of a semiconductor wafer and a display substrate with plasma. A substrate processing apparatus using plasma includes an electrostatic chuck for clamping a substrate during processing. In the related art, when the electrostatic chuck clamps the substrate, a voltage value of a power supply that is applied to the substrate is the same regardless of a condition of each process. However, in the case where the electrostatic chuck is used for a long period of time, physical properties of the electrostatic chuck and physical properties of layer values of the substrate are changed. Due to the property changes, there is a difference in a chucking force for the substrate, and therefore an etch rate is also changed.

### SUMMARY

Embodiments of the inventive concept provide a substrate processing apparatus and method for efficiently feedback controlling a chucking voltage applied to an electrostatic chuck.

In addition, embodiments of the inventive concept provide a substrate processing apparatus and method for efficiently controlling a gas flow according to property changes of apparatuses in a chamber.

The technical problems to be solved by the inventive concept are not limited to the aforementioned problems. Any other technical problems not mentioned herein will be clearly understood from the following description by those skilled in the art to which the inventive concept pertains.

According to an exemplary embodiment, an apparatus for processing a substrate includes a process chamber having a processing space inside, a support unit that supports the substrate in the process chamber, a gas supply unit that supplies a process gas into the processing space, and a plasma source that generates plasma from the process gas.

The support unit includes an electrostatic chuck that clamps the substrate using an electrostatic force, and the apparatus further includes a power supply that supplies a chucking voltage to the electrostatic chuck and a management unit that feedback controls a voltage applied to the power supply for each process and controls a heat transfer gas flow supplied between the substrate and the electrostatic chuck.

The management unit may include a first monitoring unit that monitors a physical property change of the substrate.

The physical property may be film quality information.

The management unit may include a second monitoring unit that monitors a physical property change of the electrostatic chuck.

The physical property may be information about permittivity.

The first monitoring unit and the second monitoring unit may monitor a change of a chucking force value according to the monitored physical property changes together.

The management unit may further include a first controller that performs control to compensate for the chucking voltage by feeding back a chucking force value corresponding to a preset reference value based on the monitored property changes.

The management unit may further include a third monitoring unit that monitors a change of a heat transfer gas leak flow supplied between the substrate placed on the electrostatic chuck and the electrostatic chuck, in which the change of the heat transfer gas leak flow occurs depending on the physical property changes of the substrate and the electrostatic chuck.

The management unit may further include a second controller that controls a gas flow to correspond to the fed back chucking voltage, based on the change of the heat transfer gas leak flow that is monitored by the third monitoring unit.

The management unit may feedback control a voltage and a gas flow by monitoring a physical property change for each process step while a process of the apparatus is performed.

According to an exemplary embodiment, a method for processing a substrate by collecting properties of apparatuses in a chamber includes monitoring a physical property change of the substrate, monitoring a physical property change of an electrostatic chuck, detecting whether a chucking force value is changed or not, based on outcomes of the monitoring, and performing compensation by feeding back a chucking voltage corresponding to a reference value, when a change of the chucking force value is detected.

The method may further include monitoring a change of a leak flow of a heat transfer gas supplied between the substrate placed on the electrostatic chuck and the electrostatic chuck according to a change in states of the substrate and the electrostatic chuck.

The method may further include controlling a gas flow to a value corresponding to a chucking voltage fed back based on the change of the leak flow of the gas.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a substrate processing apparatus according to the inventive concept;

FIG. 2 is a view illustrating an electrostatic chuck of FIG. 1;

FIG. 3 is a block diagram illustrating a management unit according to the inventive concept; and

FIGS. 4 and 5 are flowcharts illustrating a substrate processing method of the inventive concept.

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms such as first, second, and the like may be used to describe various components, but the components should not be limited by the terms. The terms may be used only for distinguishing one component from others. For example, without departing the scope of the inventive concept, a first component may be referred to as a second component, and similarly, the second component may also be referred to as the first component.

The terms of a singular form may include plural forms unless otherwise specified. Furthermore, in the drawings, the shapes and dimensions of components may be exaggerated for clarity of illustration.

In the entire specification, the terminology, component “˜unit,” refers to a software component or a hardware component such as an FPGA or an ASIC, and performs at least one function or operation. It should be, however, understood that the component “˜unit” is not limited to a software or hardware component. The component “˜unit” may be implemented in storage media that can be designated by addresses. The component “˜unit” may also be configured to regenerate one or more processors.

For example, the component “˜unit” may include various types of components (e.g., software components, object-oriented software components, class components, and task components), processes, functions, attributes, procedures, sub-routines, segments of program codes, drivers, firmware, micro-codes, circuit, data, data base, data structures, tables, arrays, and variables. Functions provided by a component and the component “˜unit” may be separately performed by a plurality of components and components “˜units” and may also be integrated with other additional components.

Hereinafter, a substrate processing apparatus for etching a substrate using plasma according to an embodiment of the inventive concept will be described. Without being limited thereto, however, the inventive concept is applicable to various apparatuses for processing a substrate using gas.

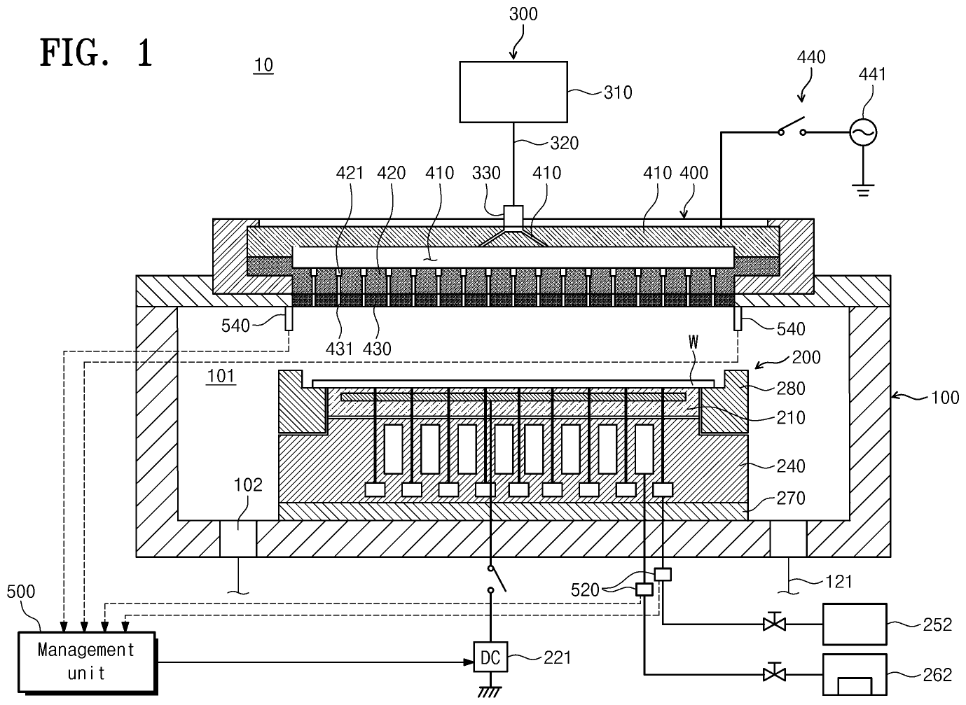

FIG. 1 is a plan view illustrating a substrate processing apparatus according to an embodiment of the inventive concept.

Referring to FIG. 1, the substrate processing apparatus 10 according to the embodiment of the inventive concept includes a process chamber 100, an electrostatic chuck 200, a gas supply unit 300, a plasma generation unit 400, and a management unit 500. The process chamber 100 has a space 101 formed therein. The internal space 101 is provided as a space in which plasma processing is performed on a substrate W. The plasma processing on the substrate W includes an etching process. An exhaust hole 102 is formed in the bottom of the process chamber 100. The exhaust hole 102 is connected with an exhaust line 121. Reaction byproducts generated during the processing and gases staying in the process chamber 100 may be discharged to the outside through the exhaust line 121. Furthermore, the pressure in the internal space 101 of the process chamber 100 is reduced to a predetermined pressure by the exhaust process.

The electrostatic chuck 200 is located in the process chamber 100. The electrostatic chuck 200 attracts and clamps the substrate W using an electrostatic force.

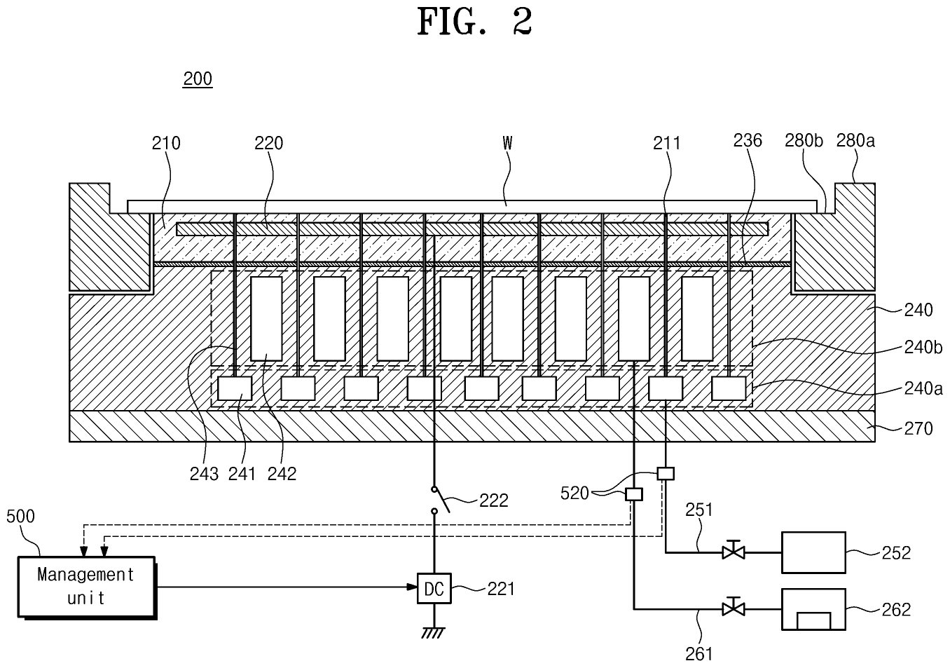

FIG. 2 is a sectional view illustrating the electrostatic chuck 200 of FIG. 1.

Referring to FIGS. 1 and 2, the electrostatic chuck 200 includes a dielectric plate 210, a lower electrode 220, a support plate 240, and an insulation plate 270.

The dielectric plate 210 is located at the top of the electrostatic chuck 200. The dielectric plate 210 is formed of a dielectric substance in a disk shape. The substrate W is placed on a top surface of the dielectric plate 210. The top surface of the dielectric plate 210 has a smaller radius than the substrate W. Hence, an edge region of the substrate W is located outside the dielectric plate 210. The dielectric plate 210 has first supply passages 211 formed therein. The first supply passages 211 extend from the top surface of the dielectric plate 210 to a bottom surface thereof. The first supply passages 211 are spaced apart from each other and serve as passages through which a heat transfer medium is supplied to a bottom surface of the substrate W. The lower electrode 220 is buried in the dielectric plate 210. The lower electrode 220 is electrically connected with a power supply 221. The power supply 221 includes a direct current (DC) power supply. A switch 222 is installed between the lower electrode 220 and the power supply 221. The lower electrode 220 may be electrically connected to, or disconnected from, the power supply 221 by turning on or off the switch 222. When the switch 222 is in an ON position, direct current is applied to the lower electrode 220. The current applied to the lower electrode 220 induces an electrostatic force between the lower electrode 220 and the substrate W, and the substrate W is clamped to the dielectric plate 210 by the electrostatic force.

The support plate 240 is located under the dielectric plate 210. The bottom surface of the dielectric plate 210 and a top surface of the support plate 240 may be bonded together by an adhesive 236. The support plate 240 may be made of aluminum. The top surface of the support plate 240 may have a step such that a central region is located in a higher position than an edge region. The central region of the top surface of the support plate 240 has an area corresponding to that of the bottom surface of the dielectric plate 210 and is bonded to the bottom surface of the dielectric plate 210. A first circulation passage 241, a second circulation passage 242, and second supply passages 243 are formed in the support plate 240.

The first circulation passage 241 serves as a passage through which the heat transfer medium circulates. The first circulation passage 241 may be formed in a spiral shape in the support plate 240. Alternatively, the first circulation passage 241 may include a plurality of concentric ring-shaped passages having different radii. Each of the first circulation passages 241 may be communicated with each other. The first circulation passages 241 are formed at the same height. Hereinafter, the region of the support plate 210 where the first circulation passages 241 are formed is referred to as a first region 240a. The first region 240a is located adjacent to a bottom surface of the support plate 240. The second circulation passage 242 serves as a passage through which cooling fluid circulates. The second circulation passage 242 may be formed in a spiral shape in the support plate 240. Alternatively, the second circulation passage 242 may include a plurality of concentric ring-shaped passages having different radii. Each of the second circulation passages 242 may becommunicated with each other. Hereinafter, the region of the support plate 240 where the second circulation passages 242 are formed is referred to as a second region 240b. The second region 240b is located over the first region 240a. The second region 240b is located closer to the dielectric plate 210 than the first region 240a.

The second supply passages 243 extend upward from the first circulation passages 241 to a top surface of the support plate 240. As many second supply passages 243 as the first supply passages 211 are provided. The second supply passages 243 connect the first circulation passages 241 and the first supply passages 211.

Each of the second supply passages 243 is formed in a region between the second circulation passages 242 adjacent to the second region 240b. The first circulation passages 241 are connected to a heat transfer medium reservoir 252 through a heat transfer medium supply line 251. The heat transfer medium reservoir 252 has a heat transfer medium stored therein. The heat transfer medium includes an inert gas. According to an embodiment, the heat transfer medium includes a helium (He) gas. The helium gas is supplied to the first circulation passages 241 through the heat transfer medium supply line 251 and then supplied to the bottom surface of the substrate W through the second supply passages 243. The helium gas serves as a medium through which heat transferred from plasma to the substrate W is transferred to the electrostatic chuck 200. Ion particles contained in the plasma are attracted and moved to the electrostatic chuck 200 by an electrostatic force formed in the electrostatic chuck 200 and collide with the substrate W to perform an etching process in the process of moving to the electrostatic chuck 200. In the process in which the ion particles collide with the substrate W, heat is generated in the substrate W. The heat generated in the substrate W is transferred to the electrostatic chuck 200 through the helium gas supplied into the space between the bottom surface of the substrate W and the top surface of the dielectric plate 210. Accordingly, the substrate W may be maintained at a set temperature.

The second circulation passages 242 are connected to a cooling fluid reservoir 262 through a cooling fluid supply line 261. The cooling fluid reservoir 262 has a cooling fluid stored therein. A cooler 263 may be provided in the cooling fluid reservoir 262. The cooler 263 cools the cooling fluid to a predetermined temperature. Alternatively, the cooler 263 may be installed on the cooling fluid supply line 261. The cooling fluid supplied to the second circulation passages 242 through the cooling fluid supply line 261 cools the support plate 240 while circulating along the second circulation passages 242. The support plate 240, while being cooled, cools the dielectric plate 210 and the substrate W together to maintain the substrate W at a predetermined temperature.

The insulation plate 270 is provided under the support plate 240. The insulation plate 270 has a size corresponding to that of the support plate 240. The insulation plate 270 is located between the support plate 240 and the bottom of the process chamber 100. The insulation plate 270 is made of an insulating material and electrically insulates the support plate 240 and the process chamber 100.

A focus ring 280 is disposed on an edge region of the electrostatic chuck 200. The focus ring 280 has a ring shape and is disposed around the dielectric plate 210. A top surface of the focus ring 280 may have a step such that an outer portion 280a is located in a higher position than an inner portion 280b. The inner portion 280b of the top surface of the focus ring 280 is located at the same height as the top surface of the dielectric plate 210. The inner portion 280b of the top surface of the focus ring 280 supports the edge region of the substrate W that is located outside the dielectric plate 210. The outer portion 280a of the focus ring 280 surrounds the edge region of the substrate W. The focus ring 280 expands a region where an electric field is formed, such that the substrate W is located in the center of a region where plasma is formed. Accordingly, the plasma may be uniformly formed over the entire region of the substrate W, and thus each region of the substrate W may be uniformly etched.

The gas supply unit 300 supplies a process gas into the process chamber 100. The gas supply unit 300 includes a gas reservoir 310, a gas supply line 320, and a gas intake port 330. The gas supply line 320 connects the gas reservoir 310 and the gas intake port 330 and supplies the process gas stored in the gas reservoir 310 to the gas intake port 330. The gas intake port 330 is connected with gas supply holes 412 formed in an upper electrode 410 and supplies the process gas into the gas supply holes 412. A gas distribution plate 420 is located under the upper electrode 410. The gas distribution plate 420 has a disk shape and has a size corresponding to that of the upper electrode 410. A top surface of the gas distribution plate 420 has a step such that a central region is located in a lower position than an edge region. The top surface of the gas distribution plate 420 and a bottom surface of the upper electrode 410 form a buffer space 415 by a combination thereof. The buffer space 415 is provided as a space in which the process gas supplied through the gas supply holes 412 temporarily stays before supplied into the inner space 101 of the process chamber 100. First distribution holes 421 are formed in the central region of the gas distribution plate 420. The first distribution holes 421 extend from the top surface of the gas distribution plate 420 to a bottom surface thereof The plurality of first distribution holes 421 are spaced apart from each other by a predetermined gap. The first distribution holes 421 are connected with the buffer space 415.

A showerhead 430 is located under the gas distribution plate 420. The showerhead 430 has a disk shape. Second distribution holes 431 are formed in the showerhead 430. The second distribution holes 431 extend from a top surface of the showerhead 430 to a bottom surface thereof. The plurality of second distribution holes 431 are spaced apart from each other by a predetermined gap.

As many second distribution holes 431 as the first distribution holes 421 are provided. The second distribution holes 431 are located to correspond to the first distribution holes 421. The second distribution holes 431 are connected with the first distribution holes 421, respectively. The process gas that stays in the buffer space 415 is uniformly supplied into the process chamber 100 through the first distribution holes 421 and the second distribution holes 431.

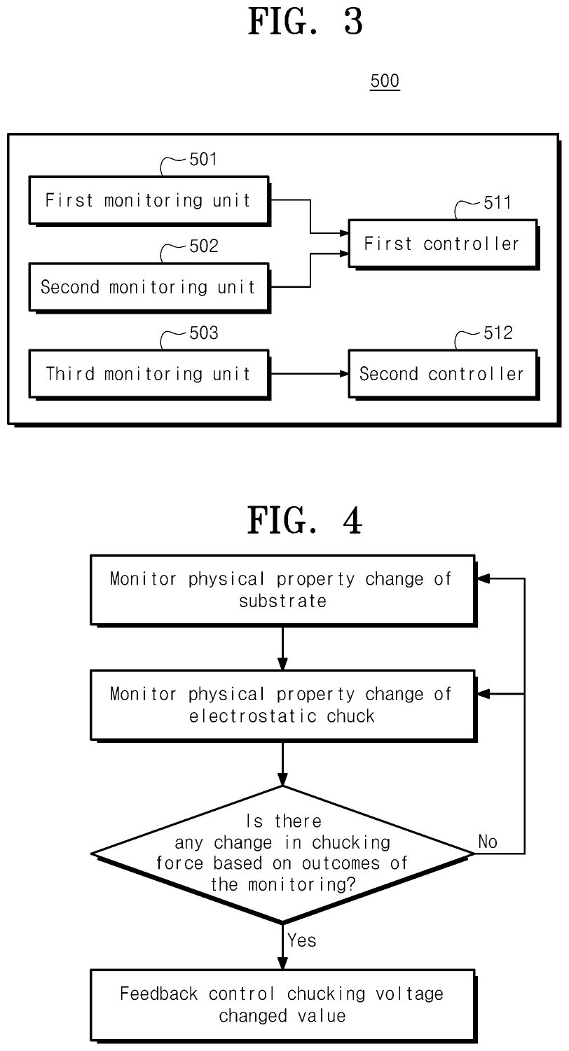

FIG. 3 is an illustrative block diagram illustrating the management unit 500 included in the substrate processing apparatus according to an embodiment of the inventive concept. Hereinafter, a configuration and a process of the management unit 500 of the substrate processing apparatus 10 of the inventive concept will be described.

As illustrated in FIG. 3, the management unit 500 of the substrate processing apparatus 10 may include a first monitoring unit 501, a second monitoring unit 502, a third monitoring unit 503, a first controller 511, and a second controller 512. The management unit 500 may monitor property changes of the electrostatic chuck 200 and the substrate W. The management unit 500 may measure a time-varying chucking force, based on an outcome of monitoring the property changes of the electrostatic chuck 200 and the substrate W. The management unit 500 may control a chucking force by adjusting a chucking voltage to correspond to the difference between the measured time-varying chucking force and a reference chucking force. Furthermore, when properties of the electrostatic chuck 200 and the substrate W are changed, a gas flow value according to the above-described heat transfer medium is also changed correspondingly. In the process of processing the substrate W, the chucking force fixing the substrate W has to remain constant, and the gas flow value generated correspondingly also has to remain constant. The management unit 500 of the inventive concept may control a gas leak flow between the electrostatic chuck 200 and the substrate W to correspond to the time-varying chucking force.

The chucking force holding the substrate W may be given by the following equation.

$$F = \frac{1}{2} * ɛ * A * \frac{V}{d}$$

In the above equation, “F” denotes the chucking force, “c” denotes permittivity, and “V” denotes an applied voltage value. Accordingly, a factor affecting the chucking force is the permittivity, and the permittivity is associated with information about film quality of the substrate W. Although not set forth herein, when those skilled in the art determine that a factor affects the chucking force, the management unit 500 of the inventive concept may monitor the factor.

The first monitoring unit 501 may monitor a physical property change according to a change in the state of the substrate W. The physical property may be information about film quality of the substrate W. The physical property may be information about the degree to which the substrate W is etched. The first monitoring unit 501 may monitor a change in the chucking force that varies depending on the film quality information of the substrate W. A reference chucking force, on the basis of which whether the chucking force is varied or not is determined, may be a chucking force required to reach a target etch rate in a corresponding process. The film quality information, which is a unique dielectric constant of the substrate W, may be obtained before processing of the substrate W. The chucking force may vary depending on the type of film on the substrate W, and therefore the chucking force for the substrate W may be more effectively controlled by using chucking information detected from the substrate W according to the film quality information.

The second monitoring unit 502 may monitor a physical property change according to a change in the state of the electrostatic chuck 200. The physical property may be information about the permittivity of a dielectric substance contained in the electrostatic chuck 200. The physical property may be information about a change in the surface state of the electrostatic chuck 200 or humidity. The second monitoring unit 502 may monitor a change in the chucking force that varies depending on a change in the permittivity of the electrostatic chuck 200. A reference chucking force, on the basis of which whether the chucking force is varied or not is determined, may be a chucking force required to reach a target etch rate in a corresponding process.

Accordingly, the first monitoring unit 501 and the second monitoring unit 502 may monitor a property change of the substrate W and a property change of the electrostatic chuck 200. While monitoring the property changes, the first monitoring unit 501 and the second monitoring unit 502 monitor whether the corresponding physical property change has an influence on the chucking force.

Although FIG. 3 illustrates one example that the management unit 500 includes the first monitoring unit 501, the second monitoring unit 502, the third monitoring unit 503, the first controller 511, and the second controller 512, this corresponds to an optimal embodiment. In another embodiment of the inventive concept, the management unit 500 may include only the first monitoring unit 501. The management unit 500 may monitor only a change in the substrate W and may perform only feedback control based on an outcome of the monitoring. In yet another embodiment, the management unit 500 may include only the second monitoring unit 502. The management unit 500 may monitor only a change in the electrostatic chuck 200 and may perform only feedback control based on an outcome of the monitoring.

The first monitoring unit 501 and the second monitoring unit 502 transfer outcomes of the monitoring to the first controller 511.

The third monitoring unit 503 may monitor a change of a heat transfer gas leak flow supplied between the electrostatic chuck 200 and the substrate W. As described above, as time passes and as a process is performed, properties of the electrostatic chuck 200 and the substrate W are changed. Therefore, the chucking force is changed, and the heat transfer gas flow is also changed. The third monitoring unit 503 monitors a change of a gas flow, and transfers an outcome of the monitoring to the second controller 512.

The first controller 511 may adjust a voltage applied to the power supply 211 to apply the reference chucking force, based on the chucking force changed according to physical property changes of the substrate W and the electrostatic chuck 200 that are monitored by the first monitoring unit 501 or the second monitoring unit 502. For example, in the case where a monitored physical property of the substrate W or the electrostatic chuck 200 is changed and a measured chucking force is decreased, a higher chucking voltage has to be applied to apply a chucking force corresponding to a set reference value. At this time, the applied chucking voltage may be determined by the above equation for the chucking force. In the case where a monitored physical property of the substrate W or the electrostatic chuck 200 is changed and a measured chucking force is increased, a lower chucking voltage has to be applied to apply a chucking force corresponding to a set reference value. At this time, the applied chucking voltage is determined by the above equation for the chucking force.

The second controller 512 may control a gas flow to correspond to a chucking voltage fed back based on a change of a gas leak flow that is monitored by the third monitoring unit 503. Even though the chucking voltage generated according to changes of the substrate W and the electrostatic chuck 200 is compensated for, when a gas flow value for processing heat generated correspondingly is not compensated for, accurate etching may not be achieved due to unbalance. Therefore, when an appropriate voltage is feedback controlled based on an outcome of monitoring a change of a gas leak flow, the second controller 512 may control a gas flow according to the voltage.

In the inventive concept, monitoring may be performed for each process. Specifically, although the film quality information of the substrate W or the permittivity of the electrostatic chuck 200 may be changed as time passes, as described above, conditions for respective processes may be different even in the process of performing the processes, and therefore physical properties of the substrate W and the electrostatic chuck 200 may be changed due to the different conditions. That is, unlike in the related art in which all process steps provide a constant voltage and a constant gas flow, in the inventive concept, processing is possible for each process, and feedback control is possible even when not only a condition in each process but also a physical property of the substrate W or the electrostatic chuck 200 in each condition is changed. As a result, the substrate W may be more efficiently processed than before.

Hereinafter, a substrate processing method according to the inventive concept will be described.

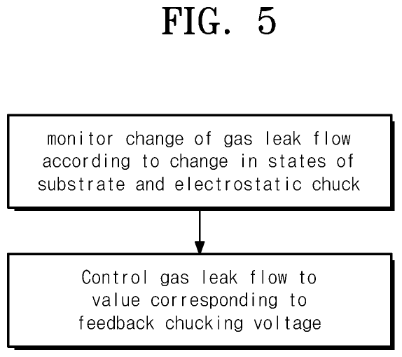

FIGS. 4 and 5 are flowcharts illustrating the substrate processing method according to the inventive concept.

Referring to FIG. 4, the substrate processing method includes a step of monitoring a physical property change of a substrate. The physical property may be film quality information. Thereafter, a physical property change of the electrostatic chuck 200 is monitored. The physical property may be permittivity. The first controller 511 of the inventive concept monitors the physical property changes and determines whether the chucking force is changed or not. When a change in the chucking force is detected, the first controller 511 calculates the difference value and then a value that has to be feedback controlled, and performs feedback control with a corresponding chucking voltage. When a change in the chucking force is not detected, the first controller 511 continually monitors physical properties of the substrate W and the electrostatic chuck 200.

Referring to FIG. 5, after the completion of the feedback control for the chucking voltage, a change of a gas leak flow according to a change in states of the corresponding substrate W and the electrostatic chuck 200 is monitored. When feedback is made with a value corresponding to the existing chucking voltage by monitoring the change of the gas leak flow, the second controller 512 may adjust the gas leak flow value to the value corresponding to the corresponding chucking voltage.

According to the embodiments of the inventive concept, the substrate processing apparatus and method may efficiently feedback control a chucking voltage applied to an electrostatic chuck.

In addition, according to the embodiments of the inventive concept, the substrate processing apparatus and method may control a gas leak flow change according to property changes of apparatuses in a chamber together.

Effects of the inventive concept are not limited to the above-described effects. Any other effects not mentioned herein may be clearly understood from this specification and the accompanying drawings by those skilled in the art to which the inventive concept pertains.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The drawings provided in the inventive concept are only drawings of the optimal embodiments of the inventive concept. The scope of the inventive concept should be determined by the technical idea of the claims, and it should be understood that the scope of the inventive concept is not limited to the literal description of the claims, but actually extends to the category of equivalents of technical value.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for processing a substrate, the apparatus comprising:
a process chamber having a processing space inside;
a support unit configured to support the substrate in the process chamber;
a gas supply unit configured to supply a process gas into the processing space; and
a plasma source configured to generate plasma from the process gas,
wherein the support unit includes an electrostatic chuck configured to clamp the substrate using an electrostatic force, and
wherein the apparatus further comprises:
a power supply configured to supply a chucking voltage to the electrostatic chuck; and
a management unit configured to feedback control a voltage applied to the power supply for each process and control a heat transfer gas flow supplied between the substrate and the electrostatic chuck.

2. The apparatus of claim 1, wherein the management unit includes a first monitoring unit configured to monitor a physical property change of the substrate.

3. The apparatus of claim 1, wherein the management unit includes a second monitoring unit configured to monitor a physical property change of the electrostatic chuck.

4. The apparatus of claim 2, wherein the physical property is film quality information.

5. The apparatus of claim 3, wherein the physical property is permittivity.

6. The apparatus of claim 2, wherein the first monitoring unit and the second monitoring unit respectively monitor a change of a chucking force value according to the monitored physical property changes together.

7. The apparatus of claim 6, wherein the management unit further includes a first controller configured to perform control to compensate for the chucking voltage by feeding back a chucking force value corresponding to a preset reference value based on the monitored property changes.

8. The apparatus of claim 7, wherein the management unit further includes a third monitoring unit configured to monitor a change of a heat transfer gas leak flow supplied between the substrate placed on the electrostatic chuck and the electrostatic chuck, wherein the change of the heat transfer gas leak flow occurs depending on the physical property changes of the substrate and the electrostatic chuck.

9. The apparatus of claim 8, wherein the management unit further includes a second controller configured to control a gas flow to correspond to the fed back chucking voltage, based on the change of the heat transfer gas leak flow that is monitored by the third monitoring unit.

10. The apparatus of claim 7, wherein the management unit feedback controls a voltage and a gas flow by monitoring a physical property change for each process step while a process of the apparatus is performed.

11. The apparatus of claim 9, wherein the management unit feedback controls a voltage and a gas flow by monitoring a physical property change for each process step while a process of the apparatus is performed.

12. The apparatus of claim 3, wherein the first monitoring unit and the second monitoring unit respectively monitor a change of a chucking force value according to the monitored physical property changes together.

13. The apparatus of claim 12, wherein the management unit further includes a first controller configured to perform control to compensate for the chucking voltage by feeding back a chucking force value corresponding to a preset reference value based on the monitored property changes.

14. The apparatus of claim 13, wherein the management unit further includes a third monitoring unit configured to monitor a change of a heat transfer gas leak flow supplied between the substrate placed on the electrostatic chuck and the electrostatic chuck, wherein the change of the heat transfer gas leak flow occurs depending on the physical property changes of the substrate and the electrostatic chuck.

15. The apparatus of claim 14, wherein the management unit further includes a second controller configured to control a gas flow to correspond to the fed back chucking voltage, based on the change of the heat transfer gas leak flow that is monitored by the third monitoring unit.

16. The apparatus of claim 13, wherein the management unit feedback controls a voltage and a gas flow by monitoring a physical property change for each process step while a process of the apparatus is performed.

17. The apparatus of claim 15, wherein the management unit feedback controls a voltage and a gas flow by monitoring a physical property change for each process step while a process of the apparatus is performed.

18. A method for processing a substrate by collecting properties of apparatuses in a chamber, the method comprising:
monitoring a physical property change of the substrate;
monitoring a physical property change of an electrostatic chuck;
detecting whether a chucking force value is changed or not, based on outcomes of the monitoring; and
performing compensation by feeding back a chucking voltage corresponding to a reference value, when a change of the chucking force value is detected.

19. The method of claim 18, further comprising:
monitoring a change of a leak flow of a heat transfer gas supplied between the substrate placed on the electrostatic chuck and the electrostatic chuck according to a change in states of the substrate and the electrostatic chuck.

20. The method of claim 19, further comprising:
controlling a gas flow to a value corresponding to a chucking voltage fed back based on the change of the leak flow of the gas.
